(19) United States
(12) Patent Application Publication
(10) Pub. No.: US 2008/0284023 A1
(43) Pub. Date: Nov. 20, 2008

(54) SEMICONDUCTOR DEVICE AND METHOD FOR MANUFACTURING BOAC/COA

(76) Inventor: Sang-Chul Kim, Gangnam-gu (KR)

Correspondence Address: SHERR & VAUGHN, PLLC, 620 HERNDON PARKWAY, SUITE 200, HERNDON, VA, 20170, US

(21) Appl. No.: 12/120,943

(22) Filed: May 15, 2008

(30) Foreign Application Priority Data
May 18, 2007 (KR) 10-2007-0048576

(51) Int. Cl. H01L 23/532; H01L 21/768

(52) U.S. Cl. 257/751; 438/653; 428/620; 257/E23.161; 257/E21.584

(57) ABSTRACT

A BOAC/COA of a semiconductor device is manufactured by forming a conductive pad over a semiconductor device, forming a passivation oxide film over the semiconductor device including the conductive pad, forming an oxide film over the entire surface of the conductive pad and the passivation oxide film, forming an oxide film pattern defining a bond pad region on the conductive pad, sequentially forming a barrier film and a metal seed layer over the oxide film pattern, the passivation oxide film and the conductive pad, forming a metal layer over the metal seed layer, planarizing the metal layer exposing the oxide film pattern and portions of the barrier film and the metal seed layer, and removing the oxide film pattern by an etching process.

The present application claims priority under 35 U.S.C. 119 to Korean Patent Application No. 10-2007-0048576 (filed on May 18, 2007), which is hereby incorporated by reference in its entirety.

### BACKGROUND

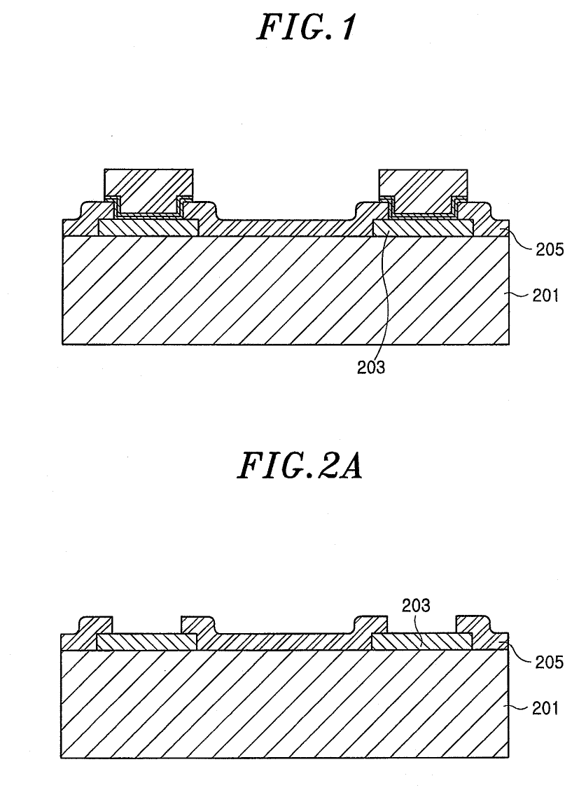

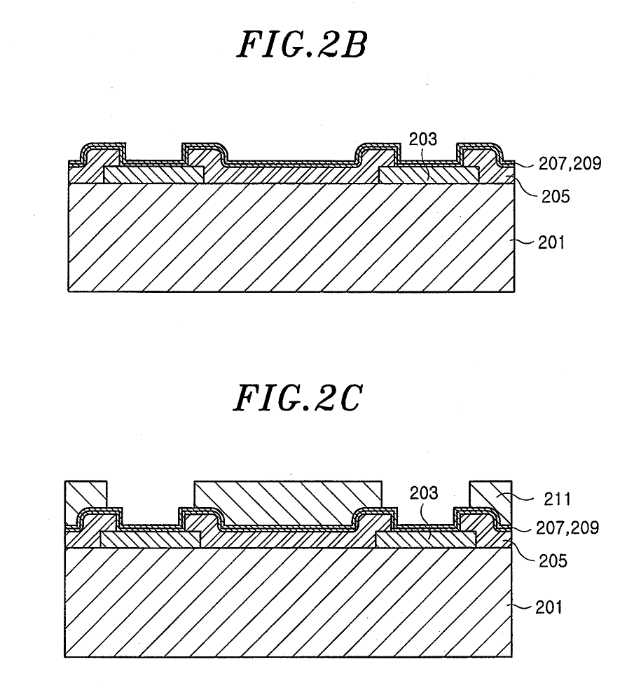

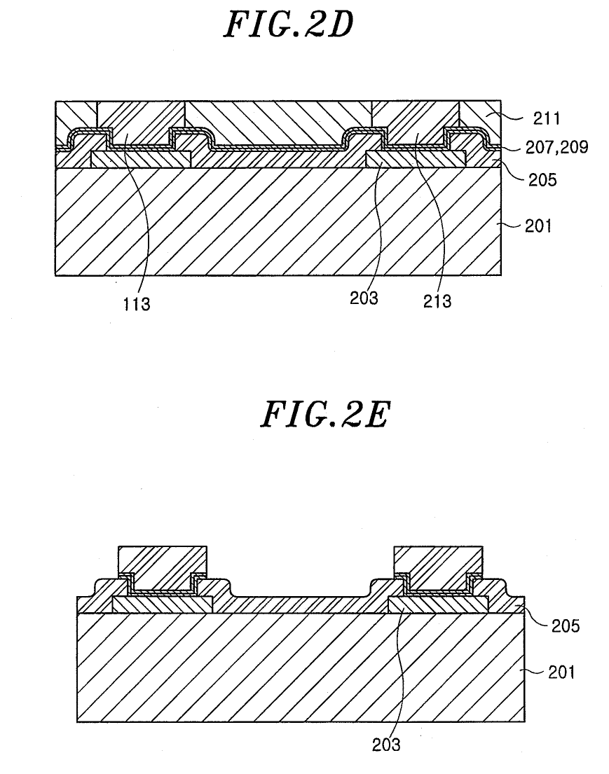

As illustrated in example FIG. 1, in a semiconductor device a bonding over active circuit structure (BOAC/COA) may be manufactured by a process scheme illustrated in example FIGS. 2A to 2E.

For example, as illustrated in example FIG. 2A, metal pad 203 and passivation oxide film 205 may be formed on and/or over semiconductor (silicon) substrate 201 by a semiconductor process. Next, barrier metal 207 which may be composed TiW may be deposited on and/or over the entire surface of metal pad 203 and passivation oxide film 205.

As illustrated in example FIG. 2B, a metal seed 209 which may be composed of Cu may then be deposited on and/or over the entire surface of the deposited barrier metal 207 using a chemical vapor deposition (CVD) process. Next, a photoresist PR may be deposited on and/or over the entire surface of metal (Cu) seed 209.

As illustrated in example FIG. 2C, a portion of the PR deposited on and/or over the entire surface may then be selectively removed by an exposure and development process which uses a reticle designed as a bond pad forming region, thereby forming PR pattern 211 defining a bond pad forming region on top of metal seed 209.

As illustrated in example FIG. 2D, metal layer 213 may then be deposited in PR pattern 211 defining a bond pad forming region by carrying out an electroplating process using a sulfuric acid bath.

As illustrated in example FIG. 2E, residual PR pattern 211 may then be removed by a streaming process, and then a portion of metal seed 209 is selectively removed, thereby implementing the manufacture of BOAC/COA.

However, in the manufacture of the BOAC/COA as described above, when a electroplating process using a sulfuric acid bath is carried out as described and illustrated in example FIG. 2D, this is contrary to a metal dual damascene technique for melting PR using the sulfuric acid bath, and hence, metal deposition is abnormally done. Further, in the case that a streaming process for selectively removing a portion of metal seed 209 is carried out, the material deposited in the bond pad forming region may also be damaged because it is the same metal material, thereby deteriorating the yield and reliability of the resultant semiconductor device.

### SUMMARY

Embodiments relate to a semiconductor device and a method for manufacturing a BOAC/COA, which can reduce costs and improve device performance by implementing a BOAC/COA by a metal dual damascene process.

Embodiments relate to a semiconductor device that can include at least one of the following: a conductive pad formed over the entire surface of a semiconductor substrate; a passivation oxide film formed on the conductive pad; a metal formed to define a bond pad region to be formed on top of the conductive pad and the passivation oxide film; a partial barrier film formed on both side walls of the metal; and a partial metal seed formed on both side walls of the barrier film.

Embodiments relate to a method for manufacturing a BOAC/COA of a semiconductor device that can include at least one of the following steps: forming a conductive pad and a passivation oxide film on a semiconductor device and depositing an oxide film over the entire surface of the conductive pad and the passivation oxide film; and then forming an oxide film pattern for defining a bond pad region to be formed on the conductive pad and the passivation oxide film; and then depositing a barrier film and a metal seed over the entire surface of the oxide film pattern formed in the step of forming an oxide film pattern; and then depositing a metal over the entire surface of the deposited metal seed; and then planarizing the deposited metal until the oxide film pattern and parts of the barrier film and metal seed are exposed; and then manufacturing a BOAC/COA by removing the oxide film pattern exposed in the step of depositing a barrier film and a metal seed by etching.

### DRAWINGS

Example FIGS. 1 and 2 illustrate a BOAC/COA structure of a semiconductor device and a method for manufacturing the same.

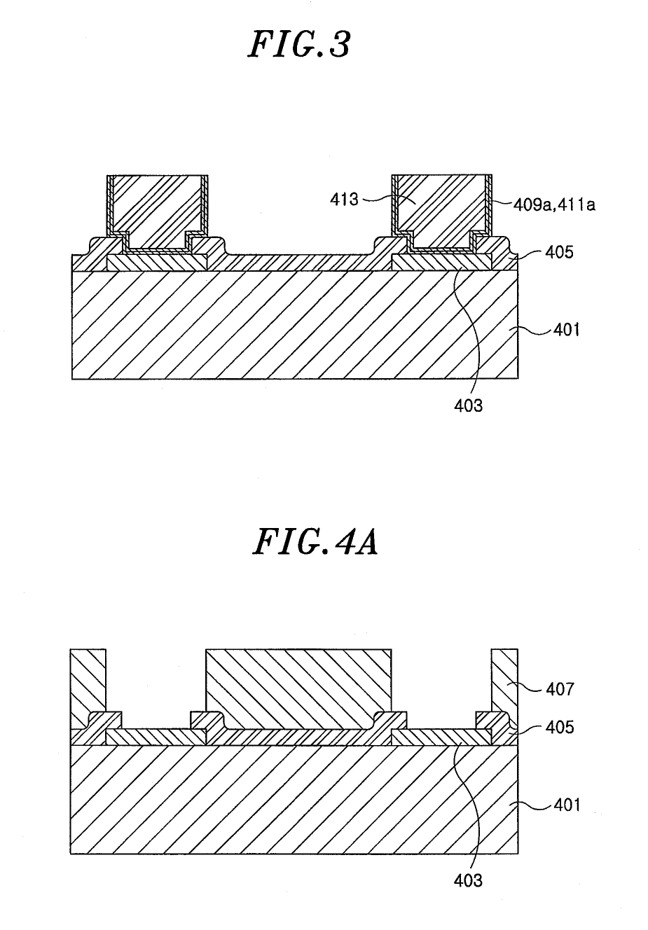

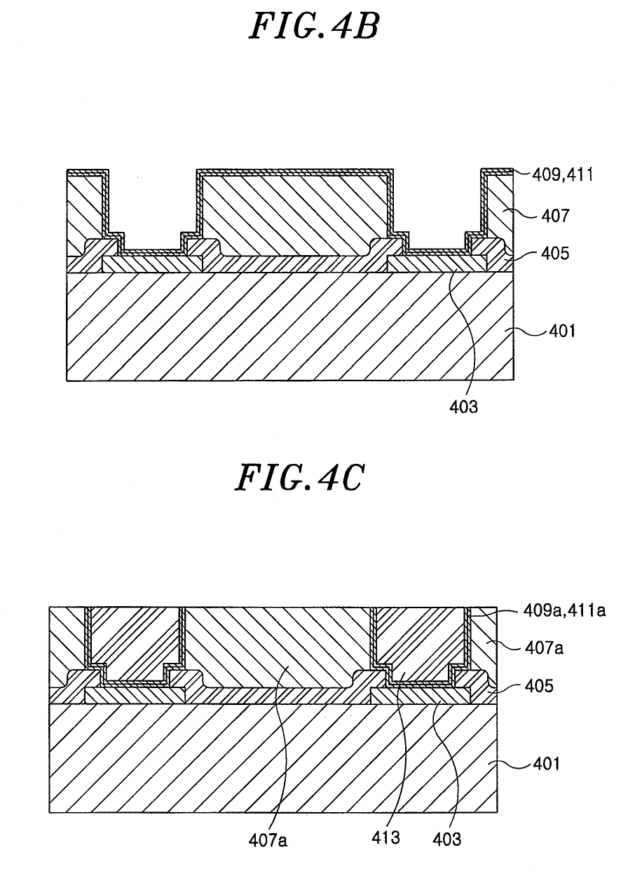

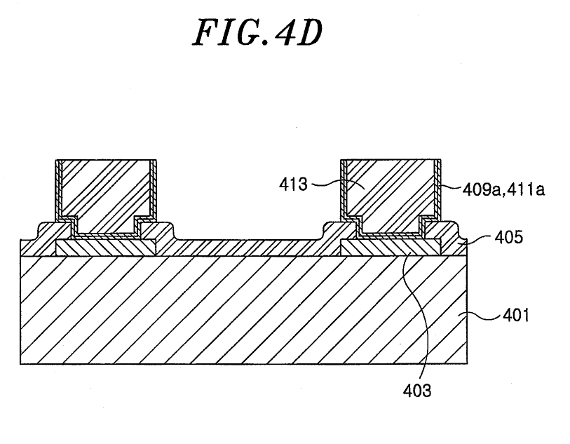

Example FIGS. 3 and 4 illustrate a BOAC/COA structure of a semiconductor device and a method for manufacturing the same, in accordance with embodiments.

### DESCRIPTION

Hereinafter, there may be a plurality of embodiments according to the present invention, and the preferred embodiment will be described in detail with reference to the accompanying drawings. For those who are skilled in the art, the purposes, features and advantages of the present invention will become more readily apparent from the following description of this embodiment.

Example FIG. 3 illustrates a vertical cross sectional view of a BOAC/COA structure of a semiconductor device that can include metal pad 403 and passivation oxide film 405 formed on and/or over semiconductor substrate 401. Metal 413 for defining a bond pad forming region can be formed on and/or over metal pad 403 and passivation oxide film 405. Metal 413 can be composed of a metal such as copper (Cu). Partial barrier metal 409a which may be composed of TiW, can be formed on both side walls of metal 413. A partial metal seed 411a which may be composed of copper (Cu) can be formed on both side walls of the formed barrier metal 409a.

The bond pad forming region can be formed by depositing an oxide film over the entire surface of metal pad 403 and passivation oxide film 405 and selectively removing a portion of the oxide film. Then, metal 413, partially exposed barrier metal 409a, and metal seed 411a can be formed by forming a barrier metal and a metal (Cu) seed on and/or over the oxide film pattern, depositing a metal (Cu) 413 on and/or over the entire surface thereof, exposing the oxide film pattern and portions of barrier metal 409a and metal seed 411a by carrying out a chemical mechanical polishing (CMP) planarization process on the deposited metal (Cu), and then selectively removing the residual oxide film pattern by an oxide film etching process such as a dry etching process. Therefore, embodiments can reduce costs and improve device performance by implementing a BOAC/COA by a metal (Cu) dual damascene process.

Example FIGS. 4A to 4D illustrate a method for manufacturing a BOAC/COA of a semiconductor device in accordance with embodiments. As illustrated in example FIG. 4A, conductive pad 403 composed of a metal can be formed on and/or over silicon substrate 401. Passivation oxide film 405 can be formed on and/or over silicon substrate 401 including conductive pad 403. An oxide film can then be deposited on and/or over the entire surface of metal pad 403 and passivation oxide film 405. A portion of the oxide film can then be selectively removed exposing metal pad 403 and thereby forming oxide film pattern 407 defining a bond pad forming region on and/or over metal pad 403 and passivation oxide film 405.

As illustrated in example FIG. 4B, barrier metal (barrier film) 409 can then be deposited on and/or over the entire surface of oxide film pattern 407, passivation oxide film 405 and metal pad 403. Metal seed 411 can then be deposited on and/or over the entire surface of barrier metal 409 by a CVD process.

As illustrated in example FIG. 4C, metal layer 413 can then be deposited on and/or over the entire surface of metal seed 411. Metal layer 413 can then be planarized by a CMP process until oxide film pattern 407a and portions of barrier metal 409a and metal seed 411a are exposed.

As illustrated in example FIG. 4D, an oxide film etching process such as a dry etching can then be performed to selectively remove residual oxide pattern 407a. Accordingly, while remaining the portions of barrier metal 409a and metal seed 411a, the BOAC/COA can be manufactured.

As described above, embodiments can improve the yield and reliability of a semiconductor process because the problem of abnormal metal deposition due to the melting of PR caused by a sulfuric acid bath can be solved. Moreover, a problem of damage caused by the same metal material in the streaming process can be solved by implementing a BOAC/COA by a metal (Cu) damascene process. Furthermore, the present invention can reduce costs and improve device performance by the improvement of the yield and reliability of a semiconductor device.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a conductive pad formed over a semiconductor substrate;
a passivation oxide film formed over the semiconductor substrate and over portions of the conductive pad;
a barrier film formed over the conductive pad and the passivation oxide film;
a metal seed layer formed over the barrier film; and
a metal layer formed over the conductive pad including the metal seed layer, the metal layer defining a bond pad region, wherein the barrier film and the metal seed layer are provided on the sidewalls of the metal layer.

2. The semiconductor device of claim 1, wherein the barrier film comprises TiW.

3. The semiconductor device of claim 1, wherein the conductive pad comprises Cu.

4. A method for manufacturing a BOAC/COA of a semiconductor device, comprising:
forming a conductive pad over a semiconductor device; and then
forming a passivation oxide film over the semiconductor device including the conductive pad; and then
forming an oxide film over the entire surface of the conductive pad and the passivation oxide film; and then
forming an oxide film pattern defining a bond pad region on the conductive pad; and then
sequentially forming a barrier film and a metal seed layer over the oxide film pattern, the passivation oxide film and the conductive pad; and then
forming a metal layer over the metal seed layer; and then
planarizing the metal layer exposing the oxide film pattern and portions of the barrier film and the metal seed layer; and then
removing the oxide film pattern by an etching process.

5. The method of claim 4, wherein the metal layer comprises Cu.

6. The method of claim 4, wherein the barrier film comprises TiW.

7. The method of claim 4, wherein planarizing the metal layer is performed by a CMP process.

8. The method of claim 4, wherein the etching process comprises a dry etching process.

9. A method comprising:
forming a metal pad over a silicon substrate; and then
forming a first oxide film as a passivation film over and contacting the silicon substrate and the metal pad; and then
forming a second oxide film over and contacting the first oxide film; and then
forming an oxide film pattern by selectively removing a portion of the second oxide film exposing a portion of the metal pad and a portion of the first oxide film; and then
forming a first metal film as a barrier film over and contacting the oxide film pattern, the first oxide film and the metal pad; and then
forming a second metal film as a seed film over the first metal film; and then
forming a third metal film over and contacting the second metal film seed; and then
forming a metal bond pad region by planarizing the third metal film exposing the oxide film pattern and portions of the first metal film and the second metal film; and then
removing the oxide film pattern exposing the first metal film and the first oxide film.

10. The method of claim 9, wherein the conductive pad is composed of a metal.

11. The method of claim 9, wherein the oxide film pattern defines a bond pad forming region.

12. The method of claim 9, wherein the second metal film is formed by a CVD process.

13. The method of claim 9, wherein planarizing the third metal film is performed by a CMP process.

14. The method of claim 9, wherein the oxide film is removed using an etching process.

15. The method of claim 9, wherein the etching process comprises a dry etching process.

16. The method of claim 9, wherein the first metal film comprises TiW.

17. The method of claim 9, wherein the second metal film comprises Cu.

18. The method of claim 9, wherein the third metal film comprises Cu.

19. The method of claim 9, wherein the second metal film and the third metal film comprise Cu.

20. The method of claim 9, wherein the first metal film comprises TiW and the second metal film and the third metal film comprise Cu.
